(19) United States
(12) Patent Application Publication
(10) Pub. No.: US 2020/0053915 A1
(43) Pub. Date: Feb. 13, 2020

(54) COMPUTER ARRANGEMENT

(71) Applicant: FUJITSU LIMITED, Kawasaki-shi (JP)

(72) Inventor: Simon Czermak, Munchen (DE)

(73) Assignee: FUJITSU LIMITED, Kawasaki-shi (JP)

(21) Appl. No.: 16/523,392

(22) Filed: Jul. 26, 2019

(30) Foreign Application Priority Data
Aug. 7, 2018 (DE) 102018119201.0

(51) Int. Cl. H05K 7/20; G06F 1/20; H05K 7/14

(52) U.S. Cl. CPC H05K 7/20727; G06F 1/20; G06F 2200/201; H05K 7/1487; H05K 7/20172

(57) ABSTRACT

The present invention relates to a computer arrangement comprising a system board, at least one processor arranged on the system board, at least one fan, at least one memory apparatus and a controller for controlling the at least one memory apparatus, wherein the at least one processor is arranged in a first area (A), the at least one memory apparatus and the controller are arranged in a second area (B), and the at least one fan is arranged between the first area (A) and the second area (B).

The present invention relates to a computer arrangement comprising a system board, at least one processor arranged on the system board, at least one fan and at least one memory apparatus.

Such computer arrangements, for example in the form of rack servers, are known from the prior art. In order to control the at least one memory apparatus, such computer arrangements have controllers (storage controllers) which are arranged on or at the system board. The at least one fan blows cooling air for cooling the processor, the controller and further components arranged on or at the system board in the direction of an area in which they are arranged on the system board.

The object of the present invention is to describe an alternative computer arrangement.

The above-mentioned object is achieved by means of a computer arrangement comprising a system board, at least one processor arranged on the system board, at least one fan, at least one memory apparatus and a controller for controlling the at least one memory apparatus. The at least one processor is arranged in a first area. The at least one memory apparatus and the controller are arranged in a second area. The at least one fan is arranged between the first area and the second area.

It is advantageous in this case that the controller for controlling the at least one memory apparatus is cooled with cold fresh air in the second area. Cooling of the controller is considerably more effective in this manner than if the controller is arranged together with the processor and further heat-generating components, for example memory modules, in the second area. Another advantage in this case is that valuable space on the system board becomes free for other components in the computer arrangement described here. In this manner, additional space for input/output cards is available in the first area on the system board.

In at least one configuration, the controller is arranged on a standard form factor PCIe card (Peripheral Component Interconnect Express card).

The advantage in this case is that the controller for controlling the at least one memory apparatus can be produced in a cost-effective manner. In this case, no specially produced controllers for controlling the at least one memory apparatus are required. Furthermore, this makes it possible to flexibly replace the controller since such standard form factor PCIe cards are widespread and readily available. For example, if a new memory technology is introduced, a controller on the market can be included in the configuration of the device and need not be independently newly developed. Standard form factor PCIe cards are, for example, full-length, half-length, full-height or low-profile PCIe cards.

In at least one configuration, a direction of an air flow generated by the at least one fan points from the first area into the second area.

In this case, the controller for controlling the at least one memory apparatus and the at least one memory apparatus are arranged in an area in which the at least one fan generates a negative pressure. The direction of the air flow generated by the at least one fan runs, in particular, substantially parallel to a main plane of extent of the system board and is also aimed, in particular, at the processor and further heat-generating components arranged on the system board.

Further advantageous configurations are described in the appended claims and the following description of exemplary embodiments on the basis of the appended figures. In the figures, identical reference signs are used for elements having a substantially identical function, but these elements need not be identical in all details. Elements having identical reference signs are sometimes described in more detail in the figures only when they first occur. These descriptions accordingly also apply to the other figures.

In the figures:

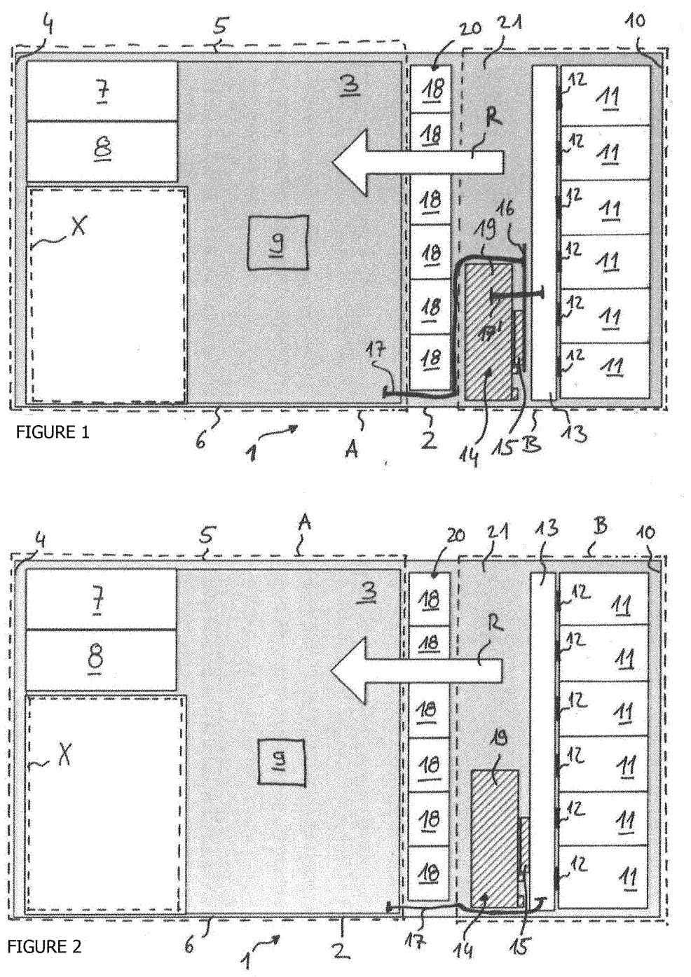

FIG. 1 shows a schematic illustration of a computer arrangement according to a first exemplary embodiment of the invention,

FIG. 2 shows a schematic illustration of a computer arrangement according to a second exemplary embodiment of the invention, and

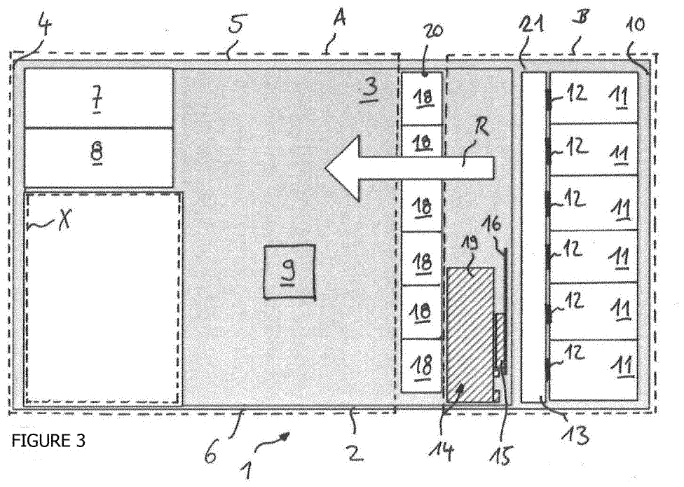

FIG. 3 shows a schematic illustration of a computer arrangement according to a third exemplary embodiment of the invention.

FIG. 1 shows a schematic illustration of a computer arrangement 1 according to a first exemplary embodiment of the invention. FIG. 1 shows a plan view of the computer arrangement 1. In this exemplary embodiment, the computer arrangement 1 is a rack server with a height unit. However, such an arrangement can also be used in any desired other rack servers or other computer systems.

The computer arrangement 1 comprises a chassis 2 in which a system board 3 is arranged. The system board 3 is arranged parallel to a base plate 21 of the chassis 2.

A first power supply unit 7, a second power supply unit 8, a processor 9 and further heat-generating components (not shown here), for example memory modules, are arranged on the system board 3. An area X in which input/output components (I/O components), for example I/O cards, can be arranged is also provided on the system board 3.

The first power supply unit 7 and the second power supply unit 8 are arranged at an end of the system board 3 facing a rear wall 4 of the chassis 2. This ensures simple connection of external power connections and simple removal or insertion of the power supply units 7, 8 via openings in the rear wall 4. The area X for the I/O components is likewise situated at an end of the system board 3 facing the rear wall 4. External I/O connections can thus be connected to the corresponding I/O components via interfaces in the rear wall 4.

A plurality of fans 18 are also arranged in the chassis 2. In this exemplary embodiment, six fans 18 are fastened to the base plate 21 of the chassis 2 by means of a common fan fastening 20. However, it goes without saying that more or fewer fans 18 can also be fitted to the fan fastening 20. The fans 18 are oriented in a parallel manner and generate a cooling air flow in the chassis 2 in the direction of an arrow R.

A plurality of memory apparatuses 11 are also arranged in the chassis 2. The memory apparatuses 11 are arranged in an area of a front side 10 of the chassis 2. The front side 10 is at an end of the chassis 2 opposite the rear wall 4. The memory apparatuses 11 are, for example, magnetic hard disks (Hard Disk Drives, HDDs), solid state drives (SSDs) or hybrid hard disks (Hybrid Hard Drives, HHDs).

The memory apparatuses 11 are connected to a backplane 13 by means of plug connections 12. The backplane 13 is a board which extends parallel to the front side 10 of the chassis 2 and is used to provide an electrical connection of the memory apparatuses 11 to a data bus of the computer arrangement 1. The memory apparatuses 11 can be inserted and removed via openings in the front side 10 of the chassis 2.

A controller 14 (storage controller) for controlling the memory apparatuses 11 and a midplane board 16 are arranged on a side of the backplane 13 remote from the memory apparatuses 11. The controller 14 is arranged on a standard form factor PCIe card 19 (Peripheral Component Interconnect Express card). In this exemplary embodiment, the PCIe card 19 is a card according to the standard form factor: low-profile/full-length. However, it goes without saying that other standard form factors can also be used.

The memory apparatuses 11 are constructed, for example, as a RAID system (Redundant Array of Independent Disks system).

The controller 14 controls, for example, a RAID controller of the RAID system. The controller 14 is also set up, for example, to create memory snapshots of the memory apparatuses 11, to carry out thin provisioning and/or to carry out automatic data tiering in the case of different types of memory apparatus 11.

The controller 14 is connected to the midplane board 16 via a CEM plug connector 15 (Card Electromechanical plug connector) according to the “PCI Express Card Electromechanical Specification Revision 3.0” standard dated 21 Jul. 2013.

A main plane of extent of the midplane board 16 is parallel to a main plane of extent of the backplane 13 and parallel to the front side 10 of the chassis 2. The midplane board 16 is mechanically fastened to the base plate 21. For this purpose, the base plate 21 has an appropriate mechanism which projects into the interior of the chassis 2 and entrains the midplane board 16, for example via guides. Alternatively or additionally, the midplane board 16 may be fastened to the backplane 13.

CEM plug connectors, such as the CEM plug connector 15 used here, are a widespread standard for PCIe cards, such as the standard form factor PCIe card 19 with the controller 14 used here. This makes it possible to use commercially available PCIe cards for the controller 14 in the computer arrangement 1 shown here.

The midplane board 16 is connected to a PCIe bus on the system board 3 via a cable 17. The controller 14 is therefore also connected to the PCIe bus via this connection. Alternatively, it is also possible to directly connect the controller 14 to the PCIe bus on the system board 3 via the cable 17. The controller 14 for controlling the memory apparatuses 11 is electrically connected to the backplane 13 via a further cable 17′.

The computer arrangement 1 comprises a first area A and a second area B. The first area A extends from the rear wall 4 of the chassis 2 along a part of the first side wall 5 and of the second side wall 6 of the chassis 2. In this exemplary embodiment, the first area A extends from the rear wall 4 approximately over somewhat less than two thirds of an interior of the chassis 2.

The second area B extends from the front side 10 likewise along a part of the first and second side walls 5, 6. In this exemplary embodiment, the second area B extends from the front side 10 approximately over somewhat less than one third of the interior of the chassis 2.

In this exemplary embodiment, the first area A surrounds the entire system board 3 together with the components arranged thereon. In particular, the processor 9, the power supply units 7, 8 and the further heat-generating components which are arranged on the system board 3 and are not shown here are situated in the first area A.

In this exemplary embodiment, the second area B surrounds the memory apparatuses 11, the backplane 13, the midplane board 16 and the PCIe card 19 with the controller 14.

The fans 18 are arranged between the first area A and the second area B. The fans 18 are arranged in a row parallel to the rear wall 4 and the front side 10 of the chassis 2 and are oriented in a parallel manner with respect to a direction of an air flow generated by the fans 18. The cooling air flow generated by the fans 18 in the direction of the arrow R points from the second area B into the first area A in order to cool the elements arranged in the first area A. The fans 18 draw in air from the second area B, with the result that a negative pressure is produced in the second area B. This negative pressure generates the cooling air flow in the second area B, which is used to cool the controller 14, for example.

In the exemplary embodiment shown here, the controller 14 is arranged at an end of the second area B facing the second side wall 6. Alternatively, it goes without saying that it is also possible to arrange the controller 14 and accordingly the midplane board 16 centrally between the first side wall 5 and the second side wall 6 or in an area of the first side wall 5.

FIG. 2 shows a schematic arrangement of a computer arrangement 1 according to a second exemplary embodiment of the invention. The second exemplary embodiment according to FIG. 2 is substantially the same as the first exemplary embodiment according to FIG. 1. Only important differences between the first exemplary embodiment and the second exemplary embodiment are discussed below.

According to the second exemplary embodiment according to FIG. 2, the PCIe card 19 with the controller 14 is directly plugged onto the backplane 13 via a CEM plug connector 15. According to this exemplary embodiment, a midplane board, as shown in FIG. 1, is not used. This enables an additional cost saving and a lower material consumption and a shorter amount of time when assembling the computer arrangement 1. In this exemplary embodiment, the backplane 13 is directly connected to the PCIe bus of the system board 3 via a cable 17. The backplane 13 routes signals transmitted via the cable 17 to the controller 14 via the CEM plug connector 15.

As described with respect to FIG. 1, the controller 14 can also here be centrally fitted to the backplane 13 between the first side wall 5 and the second side wall 6 or in an area of the first side wall 5.

FIG. 3 shows a schematic arrangement of a computer arrangement 1 according to a third exemplary embodiment of the invention. The third exemplary embodiment according to FIG. 3 is substantially the same as the exemplary embodiment according to FIG. 1. Only important differences between the third exemplary embodiment and the first exemplary embodiment are discussed below.

According to the third exemplary embodiment according to FIG. 3, the system board 3 extends not only in the first area A but also into the second area B. According to the third exemplary embodiment, the system board 3 extends almost to the backplane 13.

In this third exemplary embodiment, the fans 18 are not fastened to the base plate 21 of the chassis 2 but rather to the system board 3 via the fan fastening 20. The midplane board 16 is plugged directly onto the system board 3 by means of a CEM plug connector. Alternatively, it would also be possible to dispense with the midplane board 16 in this exemplary embodiment and to plug the PCIe card 19 with the controller 14 directly onto the system board 3 by means of the CEM plug connector 15. In this case, the PCIe card 19 would not be arranged parallel to the system board 3 in the computer arrangement 1, but rather perpendicular to the system board 3. In both cases, the controller 14 can be electrically connected to a PCIe bus on the system board 3 without an additional cable, as is used according to the first and second exemplary embodiments.

As described with respect to FIG. 1, the controller 14 can also here be centrally fitted to the backplane 13 between the first side wall and the second side wall 5, 6 or in an area of the first side wall 5.

The exemplary embodiments described here have the common feature that cooling of the controller 14 is effectively ensured by the negative pressure generated by the fans 18 in the second area B. In particular, the controller 14 is not cooled with heated exhaust air from components arranged on the system board 3. In addition, a slot in the area X for I/O components is not occupied by the PCIe card 19 on which the controller 14 is arranged, which results in a higher I/O bandwidth of the computer arrangement 1. Such slots for I/O components are available only in a greatly limited number, in particular in rack servers with a height unit. In addition, efficient connection of the controller 14 to the memory apparatuses 11 is ensured by virtue of both the controller 14 and the memory apparatuses 11 being arranged in the second area B.

The use of a midplane board 16, as shown according to FIGS. 1 and 3, makes it possible to connect the PCIe card 19 with the controller 14 to the backplane 13 even when no space for connecting the CEM plug connector 15 is available on the backplane 13. In addition, no reserve costs for connecting the CEM plug connector 15 to the backplane 13 arise in this manner, which is advantageous if a system configuration does not require a controller 14 and the latter can be dispensed with.

### LIST OF REFERENCE SIGNS

1 Computer arrangement

2 Chassis

3 System board

4 Rear wall of the chassis

5 First side wall of the chassis

6 Second side wall of the chassis

7 First power supply unit

8 Second power supply unit

9 Processor

10 Front side of the chassis

11 Memory apparatus

12 Plug connection

13 Backplane

14 Controller

15 CEM plug connector

16 Midplane board

17, 17′ Cable

18 Fan

19 Standard form factor PCIe card

20 Fan fastening

21 Base plate of the chassis

A First area

B Second area

X Area for I/O components

R Arrow

1. Computer arrangement comprising a system board, at least one processor arranged on the system board, at least one fan, at least one memory apparatus and a controller for controlling the at least one memory apparatus, wherein the at least one processor is arranged in a first area (A), the at least one memory apparatus and the controller are arranged in a second area (B), and the at least one fan is arranged between the first area (A) and the second area (B).

2. Computer arrangement according to claim 1, wherein the controller is arranged on a standard form factor PCIe card.

3. Computer arrangement according to claim 1, wherein a direction of an air flow generated by the at least one fan points from the second area (B) into the first area (A).

4. Computer arrangement according to claim 1, wherein the controller is arranged between the at least one memory apparatus and the at least one fan.

5. Computer arrangement according to claim 1, also comprising a backplane which is arranged between the at least one memory apparatus and the controller, wherein the backplane has at least one connection for the at least one memory apparatus.

6. Computer arrangement according to claim 5, also comprising a midplane board which is arranged in the second area (B), wherein the midplane board is electrically connected to the system board, the midplane board is electrically connected to the backplane, and the controller is electrically connected to the midplane board.

7. Computer arrangement according to claim 6, wherein the midplane board is electrically connected to the system board via at least one cable, and the controller is electrically connected to the midplane board via a card electromechanical plug connector.

8. Computer arrangement according to claim 5, wherein the controller is electrically connected to the backplane, and the system board is electrically connected to the backplane.

9. Computer arrangement according to claim 8, wherein the controller is electrically connected to the backplane via a card electromechanical plug connector, and the system board is electrically connected to the backplane via at least one cable.

10. Computer arrangement according to claim 1, wherein the system board is completely arranged in the first area (A).

11. Computer arrangement according to claim 1, wherein the system board is arranged in the first area (A) and at least partially extends into the second area (B).
